(19) United States
(12) Patent Application Publication
(10) Pub. No.: US 2010/0263707 A1
(43) Pub. Date: Oct. 21, 2010

(54) BASE STRUCTURE FOR III-V SEMICONDUCTOR DEVICES ON GROUP IV SUBSTRATES AND METHOD OF FABRICATION THEREOF

(76) Inventors: Dan Daeweon Cheong, Richmond Hill (CA); Rafael Nathan Kleiman, Hamilton (CA); Manuela Peter, Toronto (CA); Nicholas Komarnycky, Kitchener (CA); Bradley Joseph Robinson, Hamilton (CA); John Stewart Preston, Toronto (CA)

Correspondence Address: CHRISTINE JOHNSON ESQ., 151 Trenton Rd., Fairless Hills, PA, 19030, US

(21) Appl. No.: 12/762,256

(22) Filed: Apr. 16, 2010

Related U.S. Application Data
(60) Provisional application No. 61/202,899, filed on Apr. 17, 2009.

(51) Int. Cl. H01L 31/05; C30B 23/02; H01L 21/20

(52) U.S. Cl. 136/244; 117/101; 136/256; 438/508; 257/E21.09

(57) ABSTRACT

The structure presented herein provides a base structure for semiconductor devices, in particular for III-V semiconductor devices or for a combination of III-V and Group IV semiconductor devices. The fabrication method for a base substrate comprises a buffer layer, a nucleation layer, a Group IV substrate and possibly a dopant layer. There are, in a general aspect, two growth steps: firstly the growth of a lattice-matched III-V material on a Group IV substrate, followed by secondly the growth of a lattice-mismatched III-V layer. The first layer, called the nucleation layer, is lattice-matched or closely lattice-matched to the Group IV substrate while the following layer, the buffer layer, deposited on top of the nucleation layer, is lattice-mismatched to the nucleation layer. The nucleation layer can further be used as a dopant source to the Group IV substrate, creating a p-n junction in the substrate through diffusion. Alternatively a separate dopant layer may be introduced.

### CROSS-REFERENCE TO RELATED APPLICATION

This application claims priority to U.S. Provisional Application No. 61/202,899, titled “Base Structure For III-V Semiconductor Devices On Group IV Substrates And Method Of Fabrication Thereof” and filed on Apr. 17, 2009, the entire contents of which are incorporated herein by reference.

### FIELD OF THE INVENTION

The present invention relates to base structures for building semiconductor devices with Group III-V or II-VI materials, and their methods of fabrication.

### BACKGROUND OF THE INVENTION

The epitaxial growth of lattice-matched or lattice-mismatched materials of Group III-V and Group II-VI on Group IV substrates has been an important technical research topic for a wide range of optoelectronic device applications such as high performance multi-junction solar cells, lasers and detectors. In particular, crystalline silicon has been a very attractive substrate material due to the already well established and advanced semiconductor device fabrication methods and its lower cost when compared to Ge or III-V substrates.

Geisz et al. (J. F. Geisz et al., “Lattice-matched GaNPAs-on-silicon tandem solar cells,” IEEE Conference Record of the Thirty-first Photovoltaic Specialists Conference, pp 695-698, 2005) reported the growth of lattice-matched GaNPAs on silicon tandem solar cells. The substrate was p-type silicon and a GaP layer was used as a nucleation layer upon which all solar cell device layers were lattice-matched. Unfortunately, the short minority carrier diffusion length of the diluted nitride material can be problematic for high device performance.

Chang et al. (J. C. P. Chang et al., “Incoherent interface of InAs grown directly on GaP (001),” Appl. Phys. Lett. 69 (7), PP 981-983, 1996) reported the growth of a lattice-mismatched InAs layer on top of a GaP buffer layer, that in turn was grown on a III-V substrate, namely GaP. The quality of the GaP buffer was reported to be critical to the growth of InAs.

US patent 2008/0035939A1 to N. Puetz et al. demonstrated the growth of lattice-matched layers of GaAs on GaInP on AlAs layers on a Ge substrate where AlAs served as a nucleation layer on a Ge substrate improving the morphology of the devices and provided for a p-n junction near the surface of Group IV substrate.

Akahane et al. (Kouichi Akahane et al., “Heteroepitaxial growth of GaSb on Si (001) substrates,” Journal of Crystal Growth 264, pp 21-25, 2004) reported, that an AlSb buffer layer acts as a surfactant in the hetero-epitaxial growth of GaSb on silicon substrates, preventing the generation and propagation of dislocations in GaSb.

### SUMMARY OF THE INVENTION

The present invention provides a method of forming a base structure for opto-electronic devices and semiconductor devices including multi-junction solar cells and opens up the possibility of forming a wide range of devices on top of Group IV substrates. This is achieved through the use of a lattice-mismatched buffer layer on top of a lattice-matched nucleation layer that is grown on top of a Group IV substrate. In addition, a dopant layer may be introduced to the structure in order to create a p-n junction in the Group IV substrate.

Accordingly, in a first aspect, there is provided a base structure for fabricating semiconductor devices comprising (a) a Group IV material substrate; (b) a nucleation layer deposited on the substrate, the nucleation layer comprising a Group III-V material, wherein the nucleation layer is one of closely lattice matched and lattice matched to the substrate; and (c) a buffer layer deposited on the nucleation layer, the buffer layer comprising a III-V material, wherein the buffer layer is lattice mismatched to the nucleation layer.

The substrate preferably comprises one of an intrinsic Group IV semiconductor, a Group IV semiconductor alloy, and a doped Group IV semiconductor, and is preferably silicon or germanium. The substrate may comprise a specific crystallographic orientation wherein a surface of the substrate comprises an off-axis angle between 0 and 10 degrees.

The nucleation layer preferably comprises one of a III-P material and a III-P alloy, wherein a Group III component of the III-P material comprises at least one of the elements Al and Ga, or comprises one of a III-As material and a III-As alloy, wherein a Group III component of the III-As material comprises at least one of the elements Al or Ga, and preferably has a thickness of less than approximately 50 nm. The nucleation layer may comprise an element that contributes a dopant to the substrate during a thermal processing step.

The buffer layer preferably comprises a III-Sb material or alloy, wherein a Group III component of the III-Sb material or alloy comprises one or more elements selected from the group consisting of Al, Ga and In, or comprises a III-As material or alloy, wherein a Group III component of the III-As material or alloy comprises one or more elements selected from the group consisting of Al, Ga and In.

The base structure may further comprise a dopant layer, wherein the dopant layer is formed on the buffer layer, and wherein the dopant layer is one of lattice matched and closely lattice matched to the buffer layer. The dopant layer preferably comprises a material selected from the group consisting III-P, III-P alloys, III-As and III-As alloys. Alternatively, the dopant layer may be provided between the buffer layer and the nucleation layer, wherein the buffer layer is lattice mismatched to the dopant layer.

The substrate may comprise an additional dopant, wherein a p-n junction is formed within the substrate following the diffusion of the dopant from the dopant layer into the substrate layer.

The base structure preferably comprises one or more semiconductor device layers formed on an upper surface of the structure, where the semiconductor device layers preferably comprise a semiconductor material selected from the group consisting of Group III-V materials, Group II-VI materials, and a combination thereof. The base structure and the semiconductor device layers may comprise a device selected from the group consisting of lasers, detectors, and solar energy conversion devices.

The base structure may further provide a tandem solar cell, in which the substrate layer comprises a p-n junction forming a first solar cell having a first band gap, and wherein the structure further comprises semiconductor device layers formed on an upper surface of the structure; wherein the semiconductor device layers comprise a second solar cell having a second band gap, and wherein the second band gap is larger than the first band gap. The base structure may provide a triple junction solar cell device, in which additional semiconductor device layers provided between the first solar cell and the second solar cell, wherein the additional semiconductor device layers comprise a third solar cell having a band gap between that of the first and second band gaps. Alternatively, the triple junction may be provided by a base structure in which additional semiconductor device layers provided below the substrate, wherein the additional semiconductor device layers comprise a third solar cell having a band gap less than that of the first and second band gaps, and wherein the first, second and third solar cells form a triple junction solar cell device.

In another aspect, there is provided a method of fabricating a base structure for forming a semiconductor device, the method comprising the steps of: providing a Group IV semiconductor substrate; depositing a nucleation layer on the substrate, the nucleation layer comprising a Group III-V material, wherein the nucleation layer is one of closely lattice matched and lattice matched to the substrate; and depositing a buffer layer on the nucleation layer, the buffer layer comprising a III-V material, wherein the buffer layer is lattice mismatched to the nucleation layer.

The thickness of the nucleation layer is preferably less than approximately 50 nm. The nucleation layer may comprise an element that may act as a dopant to the substrate, the method further comprising the step of thermally processing the base structure to cause the transport of the dopant to the substrate, which occurs during the subsequent processing of following layers including buffer layer and device layers.

The method may further comprise the step of depositing a dopant layer onto the buffer layer, wherein the dopant layer is one of lattice matched and closely lattice matched to the buffer layer. Alternatively, the dopant layer may be deposited onto the nucleation layer prior to the step of depositing the buffer layer, wherein the buffer layer is lattice mismatched to the dopant layer. The base structure may be thermally processing to cause the transport of the dopant to the substrate, which occurs during the subsequent processing of following layers including buffer layer and device layers.

One or more semiconductor device layers may be deposited onto the buffer layer to form a semiconductor device. Preferably, the semiconductor device layers are deposited using a process selected from the group consisting of molecular beam epitaxy, chemical vapour deposition and metal organic chemical vapour deposition.

A further understanding of the functional and advantageous aspects of the invention can be realized by reference to the following detailed description and drawings.

### BRIEF DESCRIPTION OF THE DRAWINGS

The embodiments of the present invention are described with reference to the attached figures, wherein:

FIG. 1 shows a cross-sectional view of a base structure for semiconductor devices with a buffer layer, deposited on the nucleation layer on a Group IV substrate;

FIG. 2 shows a cross-sectional view of a base structure for semiconductor devices with the dopant layer, located between the nucleation layer and the buffer layer;

FIG. 3 shows a cross-sectional view of a base structure for semiconductor devices with the dopant layer, deposited on top of the buffer layer that is located on top of the nucleation layer;

FIG. 4 shows a flow chart illustrating a method of forming a semiconductor device base structure.

FIG. 5. shows a base structure that includes an AlSb layer as a buffer layer and a GaP layer as a nucleation layer on a silicon substrate;

FIG. 6. shows a base structure in which a dopant layer is inserted between an AlSb buffer layer and a GaP nucleation layer on a silicon substrate;

FIG. 7 shows a base structure in which a dopant layer is grown on an AlAs buffer layer on a GaP nucleation layer on a silicon substrate;

FIG. 8 shows a base structure that includes a GaAs layer as a device layer, an AlAs layer as a buffer layer and a GaP layer as a nucleation layer on a silicon substrate;

FIG. 9 shows a base structure that includes an InAs or an InP layer as a buffer layer and a GaP layer as a nucleation layer that is grown on top of a silicon substrate;

FIG. 10 shows a base structure that includes an AlSb as a buffer layer and an AlAs layer as a nucleation layer on a germanium substrate; and

FIG. 11 shows a base structure in which a dopant layer, comprised of GaInP, is inserted between an AlSb buffer layer and an AlAs nucleation layer on a germanium substrate.

### DETAILED DESCRIPTION OF THE INVENTION

Generally speaking, the systems described herein are directed to semiconductor device base structures incorporating Group III-V nucleation and buffer layers grown on a Group IV substrate. As required, embodiments of the present invention are disclosed herein. However, the disclosed embodiments are merely exemplary, and it should be understood that the invention may be embodied in many various and alternative forms. The Figures are not to scale and some features may be exaggerated or minimized to show details of particular elements while related elements may have been eliminated to prevent obscuring novel aspects. Therefore, specific structural and functional details disclosed herein are not to be interpreted as limiting but merely as a basis for the claims and as a representative basis for teaching one skilled in the art to variously employ the present invention. For purposes of teaching and not limitation, illustrated embodiments are directed to semiconductor device base structures incorporating Group III-V nucleation and buffer layers grown on a silicon substrate.

As used herein, the terms, “comprises” and “comprising” are to be construed as being inclusive and open ended, and not exclusive. Specifically, when used in this specification including claims, the terms, “comprises” and “comprising” and variations thereof mean the specified features, steps or components are included. These terms are not to be interpreted to exclude the presence of other features, steps or components.

As used herein, the terms “about” and “approximately, when used in conjunction with ranges of dimensions of particles, compositions of mixtures or other physical properties or characteristics, is meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present invention.

As used herein, the coordinating conjunction “and/or” is meant to be a selection between a logical disjunction and a logical conjunction of the adjacent words, phrases, or clauses. Specifically, the phrase “X and/or Y” is meant to be interpreted as “one or both of X and Y” wherein X and Y are any word, phrase, or clause.

As used herein, the term, “closely lattice-matched”, refers to any lattice-mismatch of less than approximately 0.7% between the lattice constants of two adjacent layers and the term “lattice-mismatched” refers to any lattice-mismatch greater than approximately 3% between the lattice constants of two adjacent layers.

As used herein, the term “dopant layer” refers to a layer that provides a dopant to a substrate. In a non-limiting example, a dopant layer may comprise a GaP layer where the diffusion of phosphorus, an n-type dopant in silicon, is more pronounced than that of gallium, thus the diffused phosphorus creates a p-n junction in a p-type silicon substrate.

As used herein, the term “III-V materials” or “III-V alloys” refers to the compounds formed by chemical elements from Group III and Group V from the periodic table of elements and can include binary, ternary, quaternary compounds and compounds with higher number of elements from Groups III and V.

As used herein, the term “II-VI materials” or “II-VI alloys” refers to the compounds formed by chemical elements from Group II and Group VI from the periodic table of elements and can include binary, ternary, quaternary compounds and compounds with higher number of elements from Groups II and VI.

As used herein, the term “III-P materials” or “III-P alloys” includes, but is not limiting to, AlP, GaP, InP, GaInP, AlGaP, AINP, GaNP, InNP, AlGaInP, AIPN, GaPN, InPN, AlGaNP, GaInNP, AIInNP and AlGaInNP.

In one embodiment, a base structure is provided for building semiconductor device layers on a Group IV substrate. The base structure comprises, a Group IV substrate, a Group III-V nucleation layer, and a III-V buffer layer. The structure is amenable for the deposition of additional semiconductor layers on top of the buffer layer, for example, to construct an active semiconductor device. Referring to FIG. 1, Group III-V nucleation layer 120 is deposited on Group IV substrate 110. The nucleation layer is closely lattice-matched or lattice-matched to substrate 110. Buffer layer 130 is deposited on nucleation layer 120. Buffer layer 130 is lattice-mismatched to nucleation layer 120.

The use of a closely-lattice matched or lattice matched nucleation layer on a Group IV substrate improves the morphology of subsequent active layers. The nucleation layer, which is preferably less than a critical thickness for high quality growth of a subsequent layer, provides the initial small crystal seed containing the newly forming crystals from which crystal growth proceeds. This crystal seed provides a properly ordered surface from which further growth can proceed in a well-defined crystallographic direction. The nucleation layer also acts as a source for, or a way of controlling the diffusion of dopants into the underlying substrate from either a lattice-matched or lattice-mismatched III-V layer.

The film quality of the nucleation layer 120 is critical for the quality of subsequent layers, eventually affecting the quality of the device layers. In a non-limiting example, the nucleation layer comprises GaP, which has an approximate 0.4% difference in the lattice constant relative to that of silicon. Referring to FIG. 1, the GaP layer is deposited on the silicon substrate 110 as nucleation layer 120. The thickness of GaP is preferably less than approximately 50 nm, which is a critical thickness required for high quality film.

The buffer layer improves the quality of the subsequent device layers. This is achieved by separating the active device layers from the imperfections associated with the starting surface. The use of a lattice mismatched buffer layer provides the opportunity to add materials that have different lattice constants from the substrate for the purpose of building active device layers on a substrate which may already contain an integrated circuit design or a simple p-n junction.

In the above embodiments, the Group IV substrate is preferably silicon or germanium. The substrate may further comprise a dopant, such as an n-type or p-type dopant, or alloys or other additives. In one embodiment, the substrate is selected from the group consisting of silicon, doped silicon and silicon alloys. The Group IV substrate may have a specific crystallographic orientation and its surface may have an off-axis angle between 0 and 10 degrees.

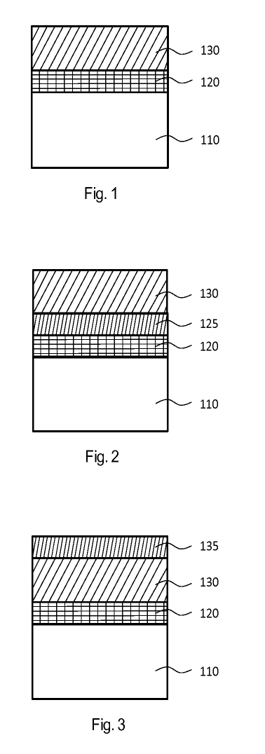

In another embodiment, a base structure is provided in which a dopant layer is incorporated into the structure. Referring to FIG. 2, the structure comprises a nucleation layer 120, a dopant layer 125 and a buffer layer 130. Dopant layer 125 provides a dopant to the Group IV substrate layer. The dopant can be either n-type (such as phosphorus and arsenic), or p-type (such as boron and aluminum). As in the previous embodiment, nucleation layer 120 is lattice matched or closely lattice matched to substrate 110. The dopant layer 125 is located between buffer layer 130 and nucleation layer 120. Buffer layer 130 is lattice-mismatched to dopant layer 125. The dopant layer 125 is closely lattice matched or lattice matched to the nucleation layer, 120. The dopant layer is preferably a III-P, III-As material, or one of its alloys (including, but not limited to, GaInP).

Alternatively, the dopant layer may be deposited on buffer layer 130 as shown in FIG. 3. Dopant layer 135 is closely lattice-matched or lattice-matched to buffer layer 130, which is lattice-mismatched to and deposited on nucleation layer 120.

In a preferred embodiment, GaP and AlAs are used as nucleation layers for silicon and germanium substrates, respectively. AlSb may be used as a buffer layer on top of the nucleation layer. The nucleation layer may comprise a III-As material or alloy, wherein the Group III comprises at least one of the elements Al or Ga or a III-P material or alloy, wherein the Group III comprises at least one of Al or Ga. In selected embodiments, the nucleation layer may comprise a source of arsenic for the n-type doping of a germanium substrate, or a source of phosphorous for the n-type doping of a silicon substrate. The nucleation layer may preferably comprise GaP or one of its alloys, or AlAs or one of its alloys, and its thickness is preferably less than 50 nm.

The buffer layer preferably comprises a III-Sb layer, wherein the Group III material or alloy comprises one or more elements selected from the group consisting of Al, Ga or In, or may comprise a III-As layer, wherein the Group III material or alloy contains at least one of the elements Al, Ga or In. The buffer layer may be a single layer or may contain more than one layer. In another embodiment, the buffer layer comprises InP or one of its alloys, or AlSb or one of its alloys.

In one embodiment, a p-n junction is formed in the substrate layer, whereby the dopant layer 125 or 135 comprises an n-type dopant while Group IV substrate 110 comprises a p-type dopant. Alternatively, dopant layer 125 or 135 may comprise a p-type dopant, and while 110 comprises an n-type dopant.

Exemplary yet non-limiting semiconductor device layer compositions for forming devices on top of the various base structure embodiments disclosed herein comprise Group III-V, Group II-VI material layers or combination from of these two Groups. In several non-limiting examples, the device may comprise a laser, detector, or solar energy conversion device.

In a preferred embodiment, GaAs is epitaxially grown on an AlAs buffer layer, which in turn is deposited on a nucleation layer. This base structure provides a base for devices which otherwise would require the use of GaAs substrates. Hence the costly GaAs substrates can be replaced with a less expensive silicon substrate.

The device may comprise a tandem solar cell device in which the top cell device layers are deposited on the base structure, and the bottom cell is formed in the substrate through the diffusion of a dopant (such as phosphorus) either from the dopant layer during subsequent process steps or other conventional methods such as spin-on-dopant source, POCl₃ or ion implantation. The bandgap of the top cell in a tandem solar cell configuration is preferably about 1.68 eV.

In a preferred embodiment, a triple junction solar cell device is provided, in which more than one solar cell junction can be formed on the substrate with materials of larger bandgaps (such as about 1.4 eV and about 1.7 eV) than silicon (1.12 eV). In another embodiment, a triple junction solar cell may be formed with one solar cell junction in silicon, another solar cell junction with a bandgap of about 0.7 eV, located below the silicon substrate and another solar cell junction above the silicon solar cells with a bandgap of about 1.7 eV. A tunnel junction is placed between two adjacent solar cell junctions to connect them with low resistance while not affecting the performance of solar cell devices.

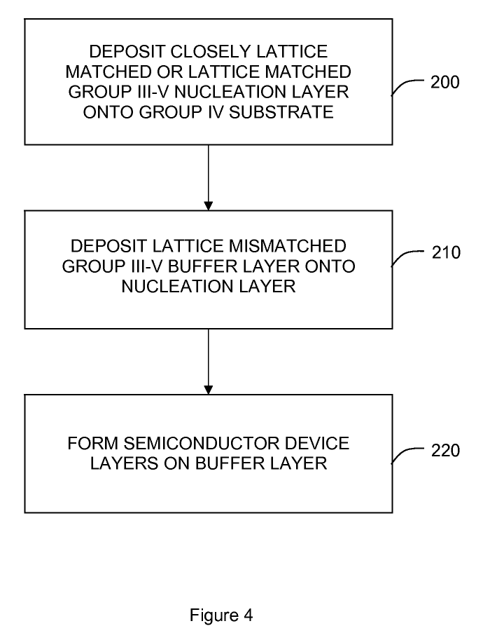

In another embodiment, there is provided a method for the fabrication of a semiconductor device base structure. As shown in FIG. 4, a thin nucleation layer comprising a Group III-V semiconductor, preferably having a thickness of less than 50 nm, is deposited onto a Group IV substrate in step 200. The nucleation layer is selected to be closely lattice matched or lattice matched with the underlying substrate. After the growth of a nucleation layer, a buffer layer is grown lattice-mismatched to the nucleation layer to accommodate various compounds which have different lattice constants from the Group IV substrate. The growth temperature of the nucleation layer plays an important role in the reduction of antiphase domains.

In a preferred embodiment, a dopant layer may be deposited (as shown in FIGS. 2 and 3) which provides a dopant to the Group IV substrate. Preferably, a “self-diffusion” process step for the dopant can be beneficial for the creation of a p-n junction in the substrate since the diffusion layer within the substrate is formed during the thermal processing of subsequent layers. This reduces the number of process steps as a separate diffusion and drive-in steps won't be necessary. However, it is preferably that the amount of dopant is optimized for the given thermal loading from subsequent thermal processes.

In addition to the above method of fabrication of a base structure, the present invention further includes a method for forming a semiconductor device on a base structure. Preferred semiconductor devices include solar cells, lasers and detectors that have a nucleation layer which is closely lattice-matched or lattice-matched to group IV substrate. The semiconductor device layers can be grown by various crystal growth methods including, but are not limited to, molecular beam epitaxy (MBE), metal organic chemical vapour deposition (MOCVD) and other varieties of chemical vapour deposition (CVD). In a preferred embodiment, the materials for the semiconductor device layers are chosen from within the Group III-V and II-VI compounds.

In a preferred embodiment, the base substrate is used for the fabrication of a multi-junction solar cell. The multi-junction solar cells are composed of solar cell junctions and tunnel junctions in between that act as a low resistance connection. The tunnel junctions are thin, typically less than 20 nm thick and heavily doped. The solar cell junction can be formed within the Group IV substrate through ion implantation of the required dopant to the substrate followed by drive-in thermal process or through diffusion of dopant from heating the dopant material or from the III-V layer above the substrate.

The following examples are presented to enable those skilled in the art to understand and to practice the present invention. They should not be considered as a limitation on the scope of the invention, but merely as being illustrative and representative thereof.

### EXAMPLES

### Example 1

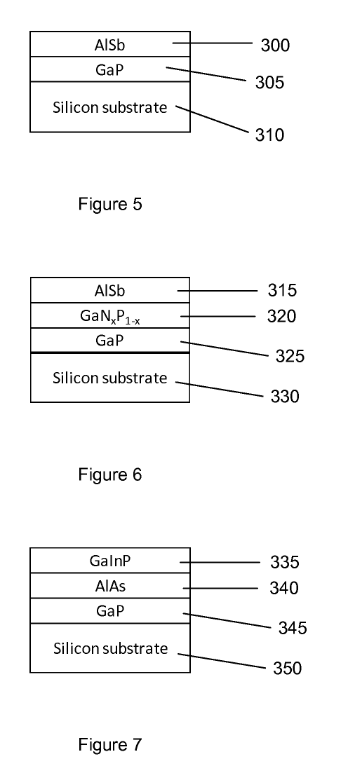

The base structure shown in FIG. 5 includes a GaP layer 305 that is closely lattice-matched to a silicon substrate 310 with a lattice-mismatch of about 0.4%. The GaP layer is grown on a boron doped p-type silicon substrate using deposition methods such as Molecular Beam Epitaxy (MBE), Metallo Organic Chemical Vapor Deposition (MOCVD) and other varieties of chemical vapour deposition (CVD). The AlSb 300 layer, which is lattice-mismatched to GaP by about 13%, is grown on top of GaP layer 305.

### Example 2

FIG. 6 shows a base structure in which a GaP layer 325 is grown on a boron doped p-type silicon substrate 330 with a thickness of less than 50 nm which is the critical thickness. The dilute nitride layer, GaNₓP₁₋ₓ layer 320 where x is about 0.02, is lattice matched to GaP layer 325. This diluted nitride layer is used as a source for the phosphorus dopant since phosphorus tends to diffuse more than gallium during the subsequent deposition cycles and thus creating a p-n homojunction in the silicon. The AlSb layer 315, which is lattice-mismatched to GaNₓP₁₋ₓ by about 13%, is deposited on GaNₓP₁₋ₓ. Any lattice-matched or lattice-mismatched device layers with the composition of III-V, II-VI or its combination in a form of binary, ternary, quaternary or higher degree of complex compounds can be grown on top of this structure to create multi-junction solar cells or for other applications.

### Example 3

In this example, shown in FIG. 7, a GaP layer 345 is grown as a nucleation layer on a boron doped p-type silicon substrate 350. The AlAs layer 340, which is lattice mismatched to GaP by about 4%, is grown on GaP layer 345. On top of AlAs layer, the lattice matched GaInP layer 335 is grown. The GaInP layer 335 contributes the phosphorus dopant, which forms a p-n homojunction in silicon substrate during the subsequent high temperature processing. The buffer layer 340 of AlAs is further a source for the arsenic dopant and may act as a barrier controlling the amount of phosphorus dopant from the GaInP layer 335. The GaP layer 345, which is adjacent to silicon substrate layer, may contribute phosphorous dopant to the silicon substrate.

### Example 4

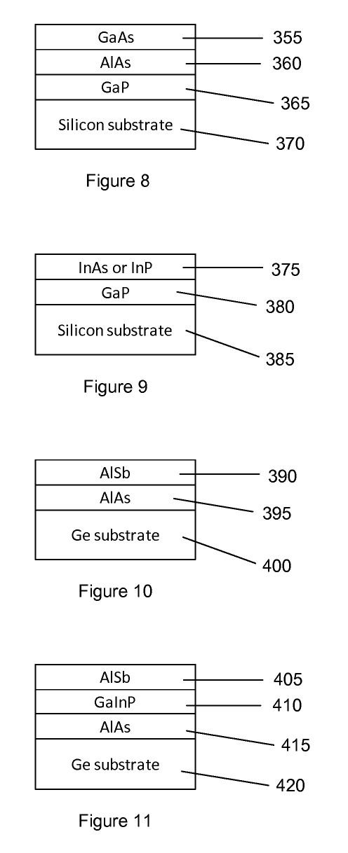

FIG. 8 shows another variation of the structure in Example 3, in which GaAs 355 is epitaxially grown on AlAs 360. This structure allows for the growth of GaAs-based devices without the need for high cost GaAs substrates. One of the applications is the triple junction solar cell whereby the bottom solar cell is formed in the silicon substrate 370, the solar cell in the middle is created from the layers of GaAs and the top solar cell is formed from InGaP.

### Example 5

The base structure shown in FIG. 9. includes a GaP nucleation layer 380 that is grown on top of a silicon substrate 385. The InAs layer 375, deposited on GaP, has a lattice mismatch of about 11% to GaP. The quality of GaP layer is critical to the growth of InAs. This structure provides a base for the growth of InGaAs/InAlAs heterostructures for long wavelength detectors, lasers and small bandgap electronic devices. In another variation, the InP, having a lattice mismatch of about 8% to GaP, is deposited on the GaP layer 380. This base structure can be used for building a photodiode.

### Example 6

FIG. 10 shows a base structure in which an AlAs layer 395 is deposited on a germanium substrate 400 and has a lattice-mismatch of less than 0.1%. The AlSb buffer layer 390, deposited on AlAs layer 395, is lattice-mismatch by about 8.4%. The AlAs nucleation layer provides an improved morphology. The AlSb buffer layer, deposited on AlAs nucleation layer, provides a base structure for device layers which are lattice-matched or lattice-mismatched to the AlSb layer.

### Example 7

In this example, shown in FIG. 11, a dopant layer, comprised of GaInP 410, is inserted between the AlAs nucleation layer 415 and AlSb buffer layer 405. The AlSb buffer layer, deposited on GaInP, has a lattice mismatch of about 8% to the GaInP layer. The phosphorus dopant from the GaInP layer 410 and the arsenic dopant from AlAs diffuse to the germanium substrate 420, forming a p-n junction with the p-type germanium substrate. The AlSb buffer layer provides for the use of materials which have different lattice constants from the germanium substrate for more applications.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

Therefore What is claimed is:

1. A base structure for fabricating semiconductor devices comprising:
(a) a Group IV semiconductor substrate;
(b) a nucleation layer deposited on said substrate, said nucleation layer comprising a Group III-V material, wherein said nucleation layer is one of closely lattice matched and lattice matched to said substrate; and
(c) a buffer layer deposited on said nucleation layer, said buffer layer comprising a III-V material, wherein said buffer layer is lattice mismatched to said nucleation layer.

2. The base structure according to claim 1 wherein said substrate comprises one of an intrinsic Group IV semiconductor, a Group IV semiconductor alloy, and a doped Group IV semiconductor.

3. The base structure according to claim 1 wherein said Group IV substrate comprises a specific crystallographic orientation and wherein a surface of said substrate comprises an off-axis angle between 0 and 10 degrees.

4. The base structure according to claim 1 wherein said substrate comprises one of silicon and germanium.

5. The base structure according to claim 1 wherein a thickness of said nucleation layer is less than approximately 50 nm.

6. The base structure according to claim 1 wherein said nucleation layer comprises one of a III-P material and a III-P alloy, wherein a Group III component of said III-P material comprises at least one of the elements Al and Ga.

7. The base structure according to claim 1 wherein said nucleation layer comprises one of a III-As material and a III-As alloy, wherein a Group III component of said III-As material comprises at least one of the elements Al or Ga.

8. The base structure according to claim 1 wherein said nucleation layer comprises an element that contributes a dopant to said substrate during a thermal processing step.

9. The base structure according to claim 1 wherein said buffer layer comprises a III-Sb material or alloy, wherein a Group III component of said III-Sb material or alloy comprises one or more elements selected from the group consisting of Al, Ga and In.

10. The base structure according to claim 1 wherein said buffer layer comprises a III-As material or alloy, wherein a Group III component of said III-As material or alloy comprises one or more elements selected from the group consisting of Al, Ga and In.

11. The base structure according to claim 1 further comprising a dopant layer, wherein said dopant layer is formed on said buffer layer.

12. The base structure according to claim 11 wherein said dopant layer is one of lattice matched and closely lattice matched to said buffer layer.

13. The base structure according to claim 11 wherein said dopant layer comprises a material selected from the group consisting III-P, III-P alloys, III-As and III-As alloys.

14. The base structure according to claim 1 further comprising a dopant layer, wherein said dopant layer is provided between said buffer layer and said nucleation layer, wherein said buffer layer is lattice mismatched to said dopant layer, wherein said dopant layer is one of closely lattice matched and lattice matched to said nucleation layer.

15. The base structure according to claim 14 wherein said dopant layer comprises a material selected from the group consisting III-P, III-P alloys, III-As and III-As alloys.

16. The base structure according to claim 11 wherein said substrate comprises an additional dopant, wherein a p-n junction is formed within said substrate following the diffusion of said dopant from said dopant layer into said substrate layer.

17. The base structure according to claim 14 wherein said substrate comprises an additional dopant, wherein a p-n junction is formed within said substrate following the diffusion of said dopant from said dopant layer into said substrate layer.

18. The base structure according to claim 1 further comprising one or more semiconductor device layers formed on an upper surface of said structure.

19. The base structure according to claim 18 wherein said one or more semiconductor device layers comprise a semiconductor material selected from the group consisting of Group III-V materials, Group II-VI materials, and a combination thereof.

20. The base structure according to claim 18 wherein said base structure and said semiconductor device layers comprise a device selected from the group consisting of lasers, detectors, and solar energy conversion devices.

21. The base structure according to claim 18 wherein said substrate layer comprises a p-n junction forming a first solar cell having a first band gap, and wherein said structure further comprises semiconductor device layers formed on an upper surface of said structure; wherein said semiconductor device layers comprise a second solar cell having a second band gap, wherein said second band gap is larger than said first band gap and said first and said second solar cells form a tandem solar cell device.

22. The base structure according to claim 21 further comprising additional semiconductor device layers provided between said first solar cell and said second solar cell, wherein said additional semiconductor device layers comprise a third solar cell having a band gap between that of said first and second band gaps, and wherein said first, second and third solar cells form a triple junction solar cell device.

23. The base structure according to claim 21 further comprising additional semiconductor device layers provided below said substrate, wherein said additional semiconductor device layers comprise a third solar cell having a band gap less than that of said first and second band gaps, and wherein said first, second and third solar cells form a triple junction solar cell device.

24. A method of fabricating a base structure for forming a semiconductor device, said method comprising the steps of:
providing a Group IV semiconductor substrate;
depositing a nucleation layer on said substrate, said nucleation layer comprising a Group III-V material, wherein said nucleation layer is one of closely lattice matched and lattice matched to said substrate; and
depositing a buffer layer on said nucleation layer, said buffer layer comprising a III-V material, wherein said buffer layer is lattice mismatched to said nucleation layer.

25. The method according to claim 24 wherein a thickness of said nucleation layer is less than approximately 50 nm.

26. The method according to claim 24 wherein said nucleation layer comprises an element that may act as a dopant to said substrate, said method further comprising the step of thermally processing said base structure to cause the transport of said dopant to said substrate.

27. The method according to claim 24 further comprising the step of depositing a dopant layer onto said buffer layer, wherein said dopant layer is one of lattice matched and closely lattice matched to said buffer layer.

28. The method according to claim 24 further comprising the step of depositing a dopant layer onto said nucleation layer prior to said step of depositing said buffer layer, wherein said buffer layer is lattice mismatched to said dopant layer.

29. The method according to claim 27 further comprising the step of thermally processing said base structure to cause the transport of said dopant to said substrate.

30. The method according to claim 28 further comprising the step of thermally processing said base structure to cause the transport of said dopant to said substrate.

31. The method according to claim 24 further comprising the step of forming a semiconductor device by depositing one or more semiconductor device layers onto said buffer layer.

32. The method according to claim 31 wherein said semiconductor device layers are deposited using a process selected from the group consisting of molecular beam epitaxy, chemical vapour deposition and metal organic chemical vapour deposition.
